(19) United States
(12) Patent Application Publication
(10) Pub. No.: US 2006/0273852 A1
(43) Pub. Date: Dec. 7, 2006

(54) Amplifiers

(75) Inventors: Chun-Jen ("Kevin") Chen, SangChung (TW); Kevin Morris, Bristol (GB)

Correspondence Address: WELSH & KATZ, LTD, 120 S RIVERSIDE PLAZA, 22ND FLOOR, CHICAGO, IL, 60606, US

(73) Assignee: University of Bristol

(21) Appl. No.: 11/431,938

(22) Filed: May 10, 2006

(30) Foreign Application Priority Data
May 12, 2005 (GB) 0509737.3

(51) Int. Cl. H03F 3/28

(52) U.S. Cl. 330/120

(57) ABSTRACT

A class E amplifier circuit comprises a first class E amplifier connected to receive a first signal and operable to amplify the first signal and to output such an amplified first signal and a second class E amplifier connected to receive a second signal related to the first signal, and operable to amplify the second signal and to output such an amplified second signal. The circuit also comprises a combiner having first and second inputs connected to receive amplified signals from the first and second class E amplifiers respectively, and phase shift means operable to introduce a phase shift between signals for combination at the combiner.

### CROSS-REFERENCE TO RELATED APPLICATION

This application claims the benefit of the filing date of British Patent Application No. 0509737.3 filed 12 May 2005 in the name of University of Bristol and entitled “Amplifiers”.

Amplifiers

The present invention relates to amplifiers, and in particular to class E amplifiers.

### BACKGROUND

Modulation schemes such as Orthogonal Frequency Division Multiplexing (OFDM) and Wideband Code-Division Multiple Access (W-CDMA) used in telecommunication systems operate with high peak-to-average power ratios. This places a requirement of a large dynamic linearity range for amplifiers used in the associated circuitry. Techniques currently employed in order for sufficient linearity to be obtained drastically reduce the power efficiency of such amplifiers.

One commonly used type of transmitter is the Envelope Elimination and Restoration, EER, transmitter.

FIG. 1 of the accompanying drawings shows a configuration of an EER transmitter. An input signal x(t), where x(t)=I+jQ, is input into a signal separation component 2, and is converted to an amplitude signal, A(t), and Cartesian signals I′(t) and Q′(t). Signal separation component 2 could be, for example a Digital Signal Processor, or a Field Programmable Gate Array. The Cartesian signals I′(t) and Q′(t) are up-converted by a quadrature up-converter 4 to a RF phase signal P(t). An example of this procedure can be found in the following article: IEEE Transactions on Microwave Theory and Techniques, Vol. 50, No. 8, August 2002, pages 1979-1983, “Out-of Band Emissions of Digital Transmissions Using Kahn EER Technique”, by Rudolph D.

The amplitude signal A(t) passes through an envelope modulator 6 and then a low pass filter 8. The output of the low pass filter 8 is an envelope signal E(t), which is used to control the bias voltage of a class E amplifier 10.

Such a state of the art EER transmitter is able to avoid some types of distortion typically associated with EER transmitters, but further distortion sources still exist. A major source of distortion comes from so-called “carrier feed though effects”. The carrier feed through effect is a result of the fact that the input signal to a class E amplifier sees a high-pass response, which has a complex impedence. The carrier feed through in a class E amplifier is higher than in a conventional linear amplifier such as class A or class AB, because the driver signal power level of the class E amplifier has to be high enough to ensure that a FET device within the amplifier can work as a switch. Carrier feed though effects result in the output of the transmitter having an undesirable DC offset.

The output, S(t), of the transmitter of FIG. 1, can be approximately represented by the following equation:
S(t)=E(t)cos(ω_{c}t+θ(t))+k cos(ω_{c}t+θ(t)+φ(E(t))) Equation 1
where S(t) is the output signal, E(t) is the envelope signal, θ(t) is the phase signal, φ(t) is the phase distortion, and k is a function which represents the DC offset voltage of the amplifier, as is deduced below.

The phase distortion φ(t) can be reduced using appropriate predistortion techniques, such that φ(t)=0. An example of this type of predistortion technique can be found in IEEE Transactions on Vehicular Technology, Vol. 53, No. 5, September 2004, pages 1468-1479, “Orthogonal Polynomials for Power Amplifier Modelling and Predistorter Design”, by Raviv Raich, Hua Qian and G. Tong Zhou. When such appropriate predistortion techniques are used, and φ(t)=0, equation 1 becomes:
S(t)=(E(t)+k)cos(ω_{c}t+θ(t)) Equation 2
where S(t) is the output signal, E(t) is the envelope signal, θ(t) is the phase signal, and it can be seen that k represents the DC offset voltage of the amplifier. The value of k is dependent upon an amplifier's characteristics and settings.

It is therefore desirable to overcome the problem of DC offset in the output of EER transmitters.

### SUMMARY OF INVENTION

According to one aspect of the present invention there is provided a class E amplifier circuit comprising: a first class E amplifier connected to receive a first signal and operable to amplify the first signal and to output such an amplified first signal; a second class E amplifier connected to receive a second signal related to the first signal, and operable to amplify the second signal and to output such an amplified second signal; a combiner having first and second inputs connected to receive amplified signals from the first and second class E amplifiers respectively; and phase shift means operable to introduce a phase shift between signals for combination at the combiner.

### BRIEF DESCRIPTION OF THE DRAWINGS

FIG. 1 illustrates a previously considered EER amplifier;

FIG. 2 illustrates an EER amplifier according to a first embodiment of the present invention;

FIG. 3 illustrates an EER amplifier according to a second embodiment of the present invention;

FIG. 4 illustrates an example of the output of a class E amplifier;

FIG. 5 illustrates an example of an output of an auxiliary class E amplifier; and

FIG. 6 illustrates a signal resulting from the combination of the signals in FIGS. 4 and 5.

### DESCRIPTION OF THE PREFERRED EMBODIMENTS

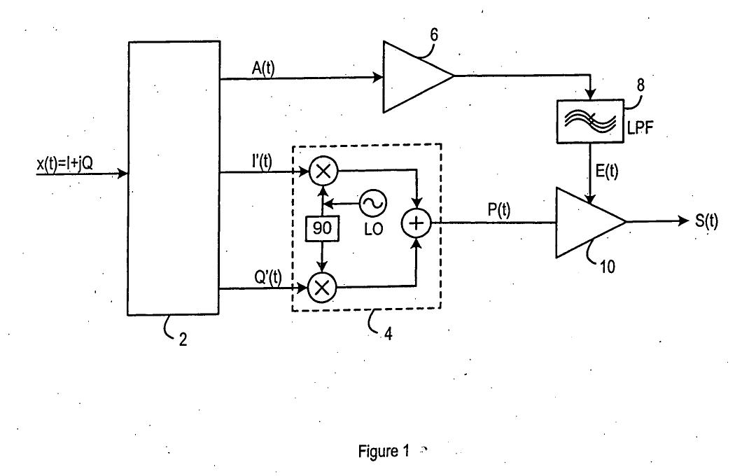

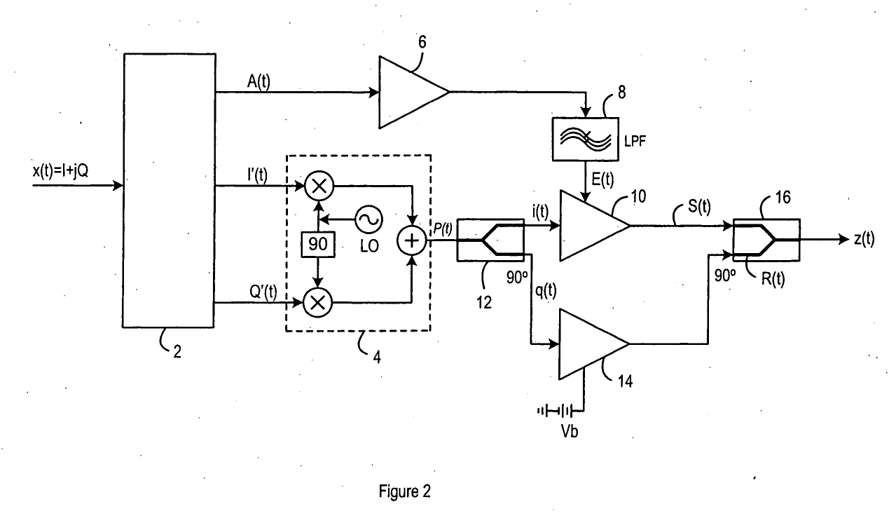

FIG. 2 illustrates a first embodiment of the present invention, which provides an EER transmitter circuit, configured such that the output, z(t), has no DC offset. That is, the output, z(t), is equivalent to the output S(t) of FIG. 1 with no DC offset.

An input signal, x(t), is input into a signal separation component 2, and converted to an amplitude signal A(t), and Cartesian signals I′(t) and Q′(t), as described in relation to FIG. 1. Again, the signal separation component 2 could be, for example a Digital Signal Processor, or a Field Programmable Gate Array. Within the signal separation component, the amplitude signal A(t) and Cartesian signals I′(t) and Q′(t) are predistorted, as discussed above. The amplitude signal A(t) passes through an envelope modulator 6 and a low pass filter 8. The output from the low pass filter 8 is an envelope signal E(t) which is used to control a first class E amplifier 10, in a manner described with reference to FIG. 1.

Two class E amplifiers are provided in the circuit of FIG. 2, the first class E amplifier 10 and a second class E amplifier 14. The first class E amplifier 10 can be referred to as a main amplifier, and the second class E amplifier 14 as an auxiliary amplifier. In one preferred embodiment, the main and auxiliary amplifiers have similar characteristics. Although it is preferable for the two amplifiers 10 and 14 to have as similar characteristics as possible, such that they provide a matched pair, embodiments of the present invention do not require this similarity.

Cartesian signals I′(t) and Q′(t) are up-converted by a quadrature up-converter 4 to a RF phase signal P(t), as described with reference to FIG. 1. The RF phase signal P(t) is input to a splitter 12, which has an in-phase output and a quadrature output. In the embodiment of FIG. 2, the splitter 12 operates to split the RF phase signal into two signals, an in-phase signal, i(t), whose phase is the same as the RF phase signal P(t); and a quadrature signal, q(t), which has a 90° phase shift with respect to the RF phase signal P(t).

The in-phase signal i(t) is supplied to the main amplifier 10. Envelope signal E(t) is supplied to the main amplifier 10 as a control signal, and is used to control the bias voltage of the main amplifier 10. Control of the bias voltage of the main amplifier serves to modulate the RF output of the amplifier 10 in accordance with the envelope signal E(t).

The output from the main amplifier can be represented by Equation 3:
S(t)=(E(t)+k)cos(ω_{c}t+θ(t)) Equation 3
where E(t) is the envelope signal, θ(t) is the phase signal, and k represents the DC offset level of the main amplifier.

The quadrature signal q(t) is supplied to the auxiliary amplifier 14.

The auxiliary amplifier 14 has a bias voltage, V_{b}, which has a magnitude such that the amplitude of the output signal of the auxiliary amplifier 14 is substantially equal to the DC offset level of the main amplifier 10.

In the embodiment of FIG. 2, the input to the auxiliary amplifier 14 is phase shifted by 90° with respect to the signal input to the main amplifier 10.

The outputs of each amplifier 10, 14 are combined using the combiner 16, which has a 90° phase difference between inputs. The output of the main amplifier 10 is connected to an in-phase input, and the output of the auxiliary amplifier 14 is connected to a quadrature input of the combiner 16. The output from the auxiliary amplifier 14 is therefore phase shifted by a further 90° upon input to the quadrature input of the combiner 16. Thus, the signal R(t), having passed through the auxiliary amplifier 14, has an overall phase shift of 180°, or π, with respect to the output S(t) of the main amplifier. The signal S(t) has undergone no phase shift.

The signal R(t), having passed through the auxiliary amplifier, can be described in a similar manner to the output S(t) of the main amplifier, where the DC offset level of the auxiliary amplifier is k′, and there is an input bias voltage V_{b} replacing the envelope signal E(t), and a phase difference of 180° with respect to S(t):
R(t)=(V_{b}(t)+k′)cos(ω_{c}t+θ(t)+π) Equation 4
therefore
R(t)=−(V_{b}(t)+k′)cos(ω_{c}t+θ(t)) Equation 5
The amplitude of the signal R(t) is therefore V_{b}+k′.

Embodiments of the invention are intended to obtain the output, z(t), of the main amplifier without the DC offset, k. Therefore, the combination of S(t) and R(t) at the combiner 16 must give S(t) without the DC offset k:
z(t)=S(t)+R(t)=E(t)cos(ω_{c}t+θ(t)) Equation 6
(E(t)+k)cos(ω_{c}(t)+θ(t))+(−Vb−k′)cos(ω_{c}(t)+θ(t))=E(t)cos(ω_{c}t+θ(t)) Equation 7
E(t)+k−V_{b}−k′=E(t) Equation 8
V_{b}=k′−k, or k′=V_{b}+k Equation 9
Hence, V_{b} is set such that V_{b}=k′−k, and the combination of R(t) and S(t) results in a signal identical to S(t) but without the DC offset.

If two amplifiers with identical characteristics, and therefore identical DC offset levels such that k=k′, were to be used, then the required V_{b} is zero. However, perfectly matched amplifiers are extremely unlikely, and so in most practical embodiments, a bias voltage V_{b} will have to be applied to the auxiliary amplifier.

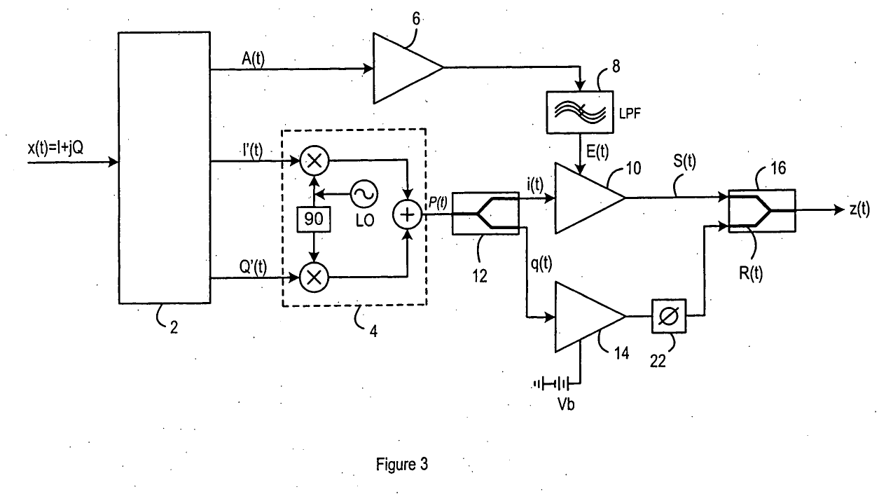

A second embodiment of the present invention is shown in FIG. 3. This embodiment differs from the embodiment of FIG. 2 only in the manner of changing the phase of the signal passing through the auxiliary amplifier 14. The phase difference does not have to be generated by the quadrature output of the splitter 12 in combination with the quadrature input of the combiner 16, as it was in the embodiment of FIG. 2. When a standard splitter and a standard combiner are used, with no quadrature inputs or outputs, the 180° phase difference can be introduced by use of at least one phase shifter 22, such that the overall phase shift is the same as that of the embodiment shown in FIG. 2. The requirement is that the signal that passed through the auxiliary amplifier 14 undergoes a total phase shift of 180° with respect to the main amplifier signal. The signal that passed through the main amplifier 10 undergoes no phase shift and therefore has a phase equal to that of the RF phase signal P(t). Signals S(t) and R(t) are therefore 180° out of phase and when combined (as in equation 6), will result in a signal equivalent to signal S(t), without the DC offset.

It will be appreciated that the 180° phase shift of the signal passing through the auxiliary amplifier could be applied in any number of ways, or any combination of the methods described above. For example, the 180° phase shifter 22 could be situated before the auxiliary amplifier, or a 90° phase shift could be introduced by a quadrature output of the splitter 12 and a further 90° phase shift could be introduced by a 90° phase shifter elsewhere.

It will also be appreciated that the splitter of the two described embodiments could be replaced by other means which provide the two class E amplifiers with related signals. These related signals could be related such that they are identical, or could simply be related such that they are similar enough for the desired result, discussed above, to be achieved. For example, the first and second signals could be identical but for a respective phase difference.

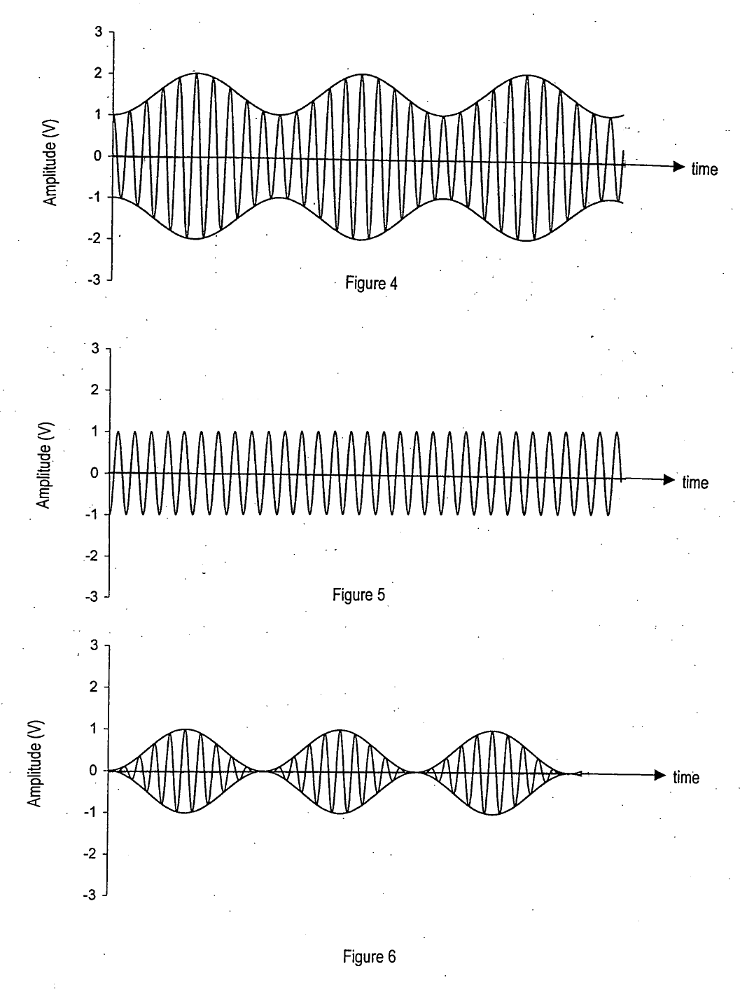

An example of the output signals S(t) and R(t) is shown in FIGS. 4 and 5, and the combination of the two example signals is shown in FIG. 6.

FIG. 4 shows the output from the main amplifier 10, signal S(t), represented by equation 3. In the example, the value of k, representing the DC offset level, is 1.0V.

FIG. 5 shows the signal R(t) from the output of the auxiliary amplifier, having been phase shifted by 180°. Since the bias voltage V_{b} of the auxiliary amplifier 14 is set so that k=k′+V_{b}, the amplitude of the signal R(t) is equal to DC offset level of the main amplifier (10), and so signal R(t) also has amplitude 1.0V. Signal R(t) is 180° out of phase with the signal S(t) from the main amplifier, as is explained above.

The effective result of combining signals S(t) and R(t) is shown in FIG. 6. The 1.0V DC offset of the signal S(t) will cancel out with the inverse phase signal R(t) with amplitude 1.0V. The output of the combiner 16 is therefore equivalent to the output of the main amplifier, without the DC offset.

The embodiments of the Invention have been described with the assumption that the phase difference between the signals for combination at the combiner is 180°. In a more general example, however, the phase difference may not be exactly 180°. This would result in reduced cancellation of the DC offset, but there may be conditions when this is acceptable, even desirable.

1. A class E amplifier circuit comprising:
a first class E amplifier connected to receive a first signal and operable to amplify the first signal and to output such an amplified first signal;
a second class E amplifier connected to receive a second signal related to the first signal, and operable to amplify the second signal and to output such an amplified second signal;
a combiner having first and second inputs connected to receive amplified signals from the first and second class E amplifiers respectively; and
phase shift means operable to introduce a phase shift between signals for combination at the combiner.

2. A class E amplifier circuit as claimed in claim 1, further comprising a splitter having first and second outputs, such that the first signal is from the first output of the splitter and the second signal is from the second output of the splitter.

3. A class E amplifier circuit as claimed in claim 1, wherein the first and second class E amplifiers include respective control inputs connected to receive respective control signals, the first and second amplified signals being dependent upon associated received control signals.

4. A class E amplifier circuit as claimed in claim 3, wherein an envelope signal is input to the first amplifier via the control input thereof.

5. A class E amplifier circuit as claimed in claim 3, wherein a bias voltage is input to the second amplifier via the control input thereof.

6. A class E amplifier circuit as in claim 1, wherein the phase shift introduced between signals for combination at the combiner is substantially equal to 180°.

7. A class E amplifier circuit as claimed in claim 2, wherein the first and second outputs of the splitter are in-phase outputs.

8. A class E amplifier circuit as claimed in claim 2, wherein the first and second outputs of the splitter provide an in-phase output and a quadrature output.

9. A class E amplifier circuit as claimed in claim 1, wherein the first and second inputs of the combiner are in-phase inputs.

10. A class E amplifier circuit as claimed claim 1, wherein the first and second inputs of the combiner provide an in-phase input and a quadrature input.

11. A class E amplifier circuit as claimed in claim 1, wherein the phase shift means comprises a 180° phase shifter.

12. A class E amplifier circuit as claimed in claim 1, wherein the phase shift means comprises two 90° phase shifters.

13. A class E amplifier circuit as claimed in claim 1, wherein the first and second amplifiers are a matched pair with substantially identical characteristics.

14. A class E amplifier circuit as claimed in claim 1, wherein the combiner is a power combiner.

15. A class E amplifier circuit comprising:
a first class E amplifier with an input and an output, a first received signal is amplified and output as an amplified first signal;
a second class E amplifier with an input and an output, a second received signal, related to the first signal, is amplified and output as an amplified second signal;
a combiner having first and second inputs coupled to receive amplified first and second signals from the first and second class E amplifiers respectively; and
phase shift circuitry to introduce a phase shift between signals being combined.

16. A class E amplifier circuit as in claim 15, wherein the first and second class E amplifiers include respective control inputs coupled to receive respective control signals, and
wherein an envelope signal is input to at least one amplifier via the respective control input thereof.

17. A class E amplifier circuit as in claim 16, wherein the phase shift introduced between signals is on the order of 180°.

18. A class E amplifier circuit as in claim 17, further comprising a splitter having first and second outputs, such that the first signal is from the first output of the splitter and the second signal is from the second output of the splitter, wherein the first and second outputs of the splitter are in-phase outputs.

19. A class E amplifier circuit as in claim 16, wherein the first and second inputs of the combiner are one of in-phase, or out of phase.

20. A class E amplifier circuit as in claim 15, wherein the phase shift circuitry comprises one of a 180° phase shifter, or multiple phase shifters that produce a 180° phase shift.
